(19) United States
(12) Patent Application Publication
(10) Pub. No.: US 2009/0127681 A1
(43) Pub. Date: May 21, 2009

(54) SEMICONDUCTOR PACKAGE AND METHOD OF FABRICATING THE SAME

(75) Inventors: Joon-seo Son, Seoul (KR); Seung-won Lim, Bucheon-si (KR); O-seob Jeon, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Fairchild Korea Semiconductor Ltd., Kyungki-do (KR)

(21) Appl. No.: 12/262,700

(22) Filed: Oct. 31, 2008

(30) Foreign Application Priority Data
Nov. 16, 2007 (KR) 10-2007-0117362

(51) Int. Cl. H01L 23/495; H01L 21/56

(52) U.S. Cl. 257/675; 438/127; 257/E23.036; 257/E21.502

(57) ABSTRACT

Provided are a semiconductor package and a method of fabricating the same. The semiconductor package includes a first die-pad on which a semiconductor chip is mounted on a bottom surface of the first die-pad, a support plate disposed adjacent to a lateral surface of the first die-pad, a support prop protruding from the support plate, and supporting the first die-pad, and a package body that encapsulates the first die-pad, the semiconductor chip, and the support plate.

### CROSS-REFERENCES TO RELATED APPLICATIONS

This application claims the benefit of Korean Patent Application No. 10-2007-0117362, filed on Nov. 16, 2007, in the Korean Intellectual Property Office, the disclosure of which is incorporated herein in its entirety by reference.

### BACKGROUND OF THE INVENTION

1. Field of the Invention

Embodiments of the present invention relate to a semiconductor package and a method of fabricating the same, and more particularly, to a semiconductor package in which a semiconductor chip and a die-pad are encapsulated by a package body, and a method of fabricating the same.

2. Description of the Related Art

The fabrication of a semiconductor package involves mounting a semiconductor chip on a die-pad included in a lead frame and forming a package body to encapsulate the semiconductor chip and the die-pad.

When the semiconductor chip is a highly integrated chip or a power circuit chip for controlling high power, a large amount of heat may be generated by the semiconductor chip. In order to dissipate the heat from the semiconductor package, the die-pad includes a heat sink layer that may be exposed outside of the package body.

When an encapsulant is injected between the heat sink layer and a mold die and cured, during an encapsulation process, mold flash may be generated on the heat sink layer, and thus, the heat emission efficiency of the heat sink layer may be reduced. Accordingly, a support pin, for applying pressure to the die-pad, may be used so that the die-pad may be maintained leveled, and closely adhered to a bottom surface of the mold die during the encapsulation process. However, after the encapsulation process is finished and the support pin is removed, a pinhole may be formed in the package body to expose the die-pad. Thus, the pinhole is filled with insulating resin in order to insulate the die-pad exposed in the pinhole.

However, since the pinhole has a relatively high aspect ratio, when the pinhole is filled with the insulating resin, voids may be easily formed. As a result, it is difficult to electrically insulate the die-pad from the air.

### SUMMARY OF THE INVENTION

Embodiments of the present invention provide a semiconductor package in which a die-pad can be closely adhered to a mold die, without using a support pin for applying pressure to the die-pad during an encapsulation process, and a method of fabricating the same.

According to an aspect of the present invention, there is provided a semiconductor package. The semiconductor package includes a die-pad on which a semiconductor chip is mounted on a bottom surface of the die-pad. A support plate is disposed adjacent to a lateral surface of the die-pad. A support prop protrudes from the support plate, and supports the die-pad. A package body encapsulates the die-pad, the semiconductor chip, and the support plate.

According to another aspect of the present invention, there is provided a semiconductor package. The semiconductor package includes a die-pad, which includes a heat sink layer and an interconnection layer disposed on a bottom surface of the heat sink layer. A power circuit chip is mounted on the interconnection layer.

An accessory heat sink is disposed adjacent to a lateral surface of the die-pad. A support prop protrudes from the accessory heat sink, and supports the die-pad. A package body encapsulates the die-pad, the power circuit chip, and the accessory heat sink and exposes the heat sink layer and the accessory heat sink.

According to yet another aspect of the present invention, there is provided a method of fabricating a semiconductor package. The method includes providing a lead frame including a die-pad on which a semiconductor chip is mounted on a bottom surface of the die-pad. The lead frame is disposed on a first mold die that includes a recess and a clamp portion enclosing the recess. A support plate having a support prop is disposed adjacent to a lateral surface of the die-pad, the support prop protrudes from the support plate, and supports the die-pad. A second mold die is disposed on the first mold die. An encapsulant is injected into a cavity between the first and second mold dies to thereby form a package body that encapsulates the die-pad, the semiconductor chip, and the support plate.

The above general embodiments and other embodiments of the invention are described in the Detailed Description with reference to the Figures. In the Figures, like numerals may reference like elements and descriptions of some elements may not be repeated.

### BRIEF DESCRIPTION OF THE DRAWINGS

The above and other features and advantages of the present invention will become more apparent by describing in detail embodiments thereof with reference to the attached drawings.

FIGS. 1A through 1E are perspective views of a method of fabricating a semiconductor package, according to an embodiment of the present invention.

FIGS. 2A through 2F are cross-sectional views of the method of fabricating the semiconductor package, according to an embodiment of the present invention.

FIGS. 3 and 4 are perspective views of support plates according to embodiments of the present invention.

FIG. 5 is a cross-sectional view of a semiconductor package according to an embodiment of the present invention.

### DETAILED DESCRIPTION OF THE INVENTION

The present invention will now be described more fully hereinafter with reference to the accompanying drawings, in which embodiments of the invention are shown. This present invention may, however, be embodied in different forms and should not be construed as limited to the embodiments set forth herein. Rather, these embodiments are provided so that this disclosure is thorough and complete and fully conveys the scope of the invention to one skilled in the art.

It will be understood that although the terms first and second are used herein to describe various members, devices, regions, layers, and/or sections, the members, devices, regions, layers and/or sections should not be limited by these terms. These terms are only used to distinguish one member, device, region, layer or section from another member, device, region, layer or section. Thus, for example, a first member, device, region, layer, or section discussed below could be termed a second member, device, region, layer, or section without departing from the teachings of the present invention.

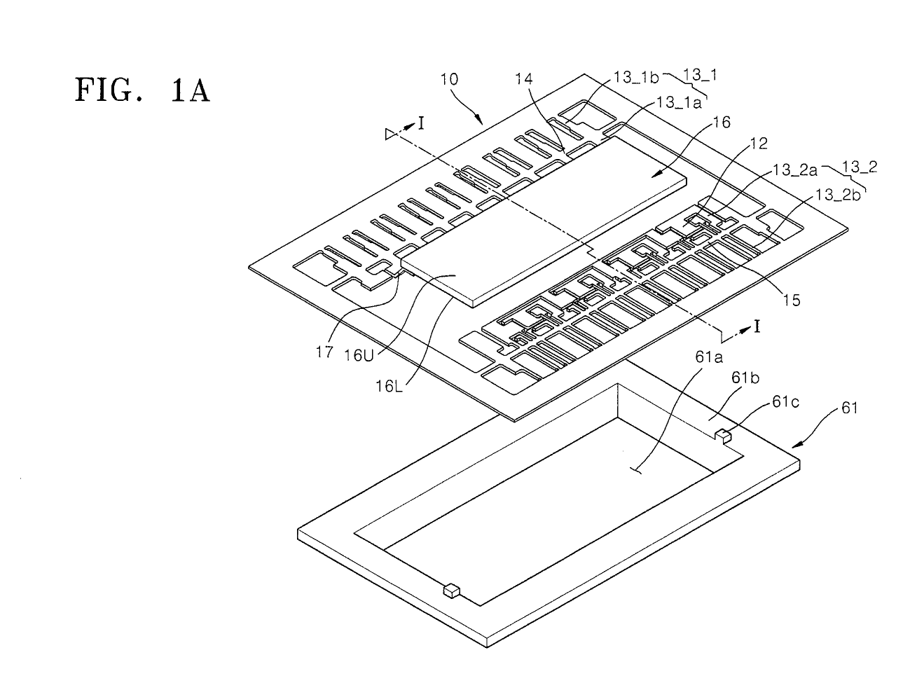

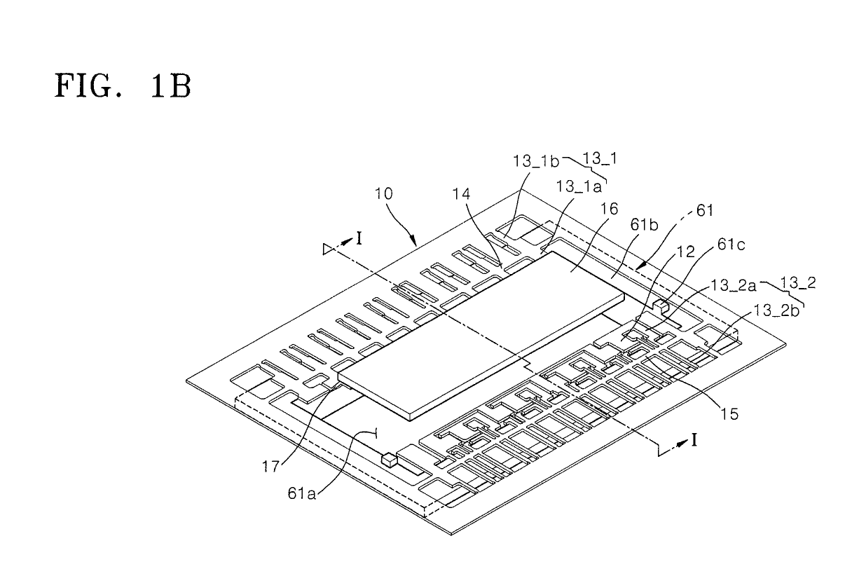

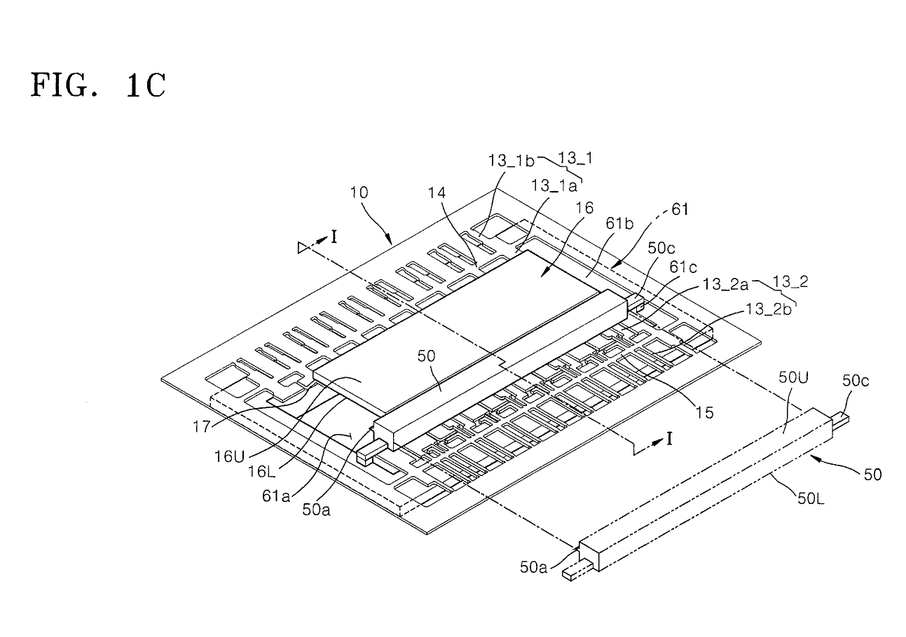

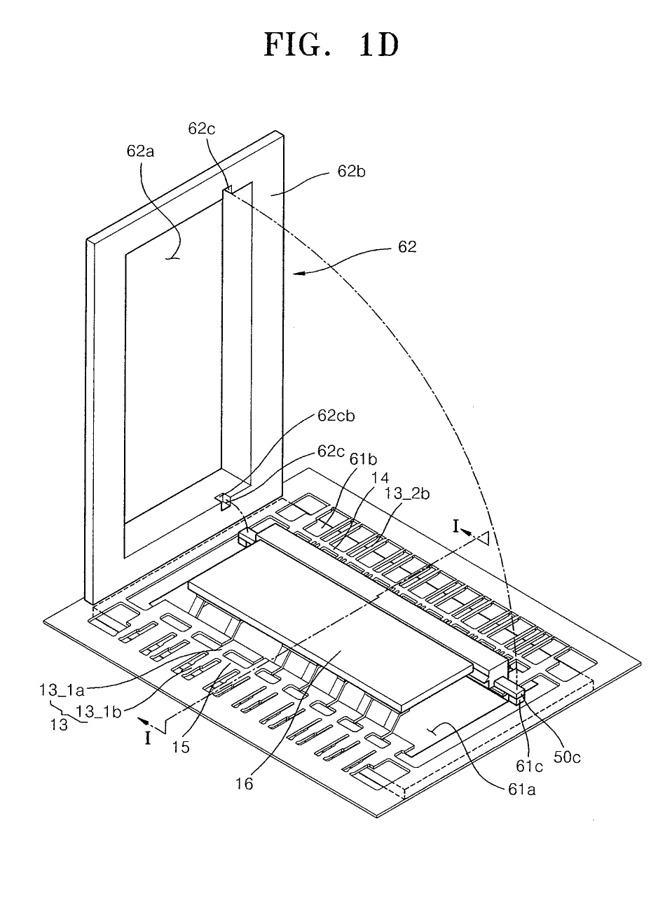

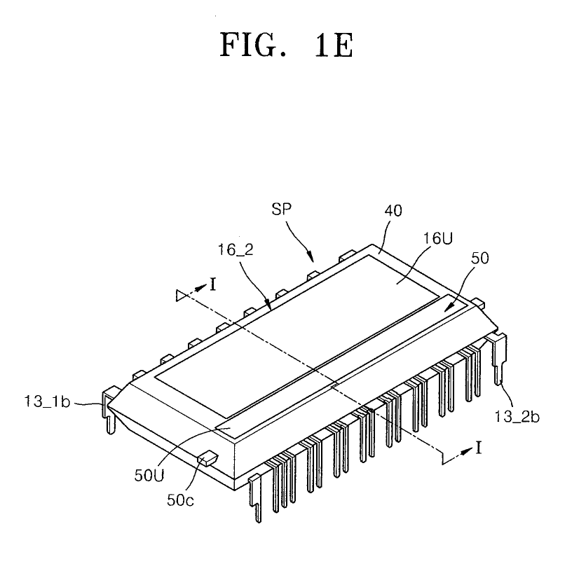

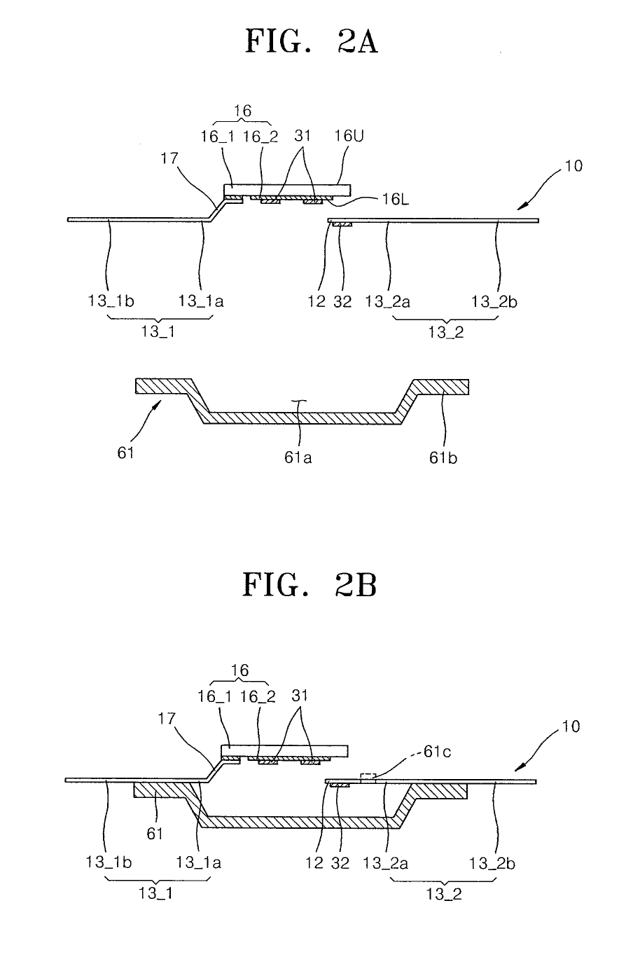

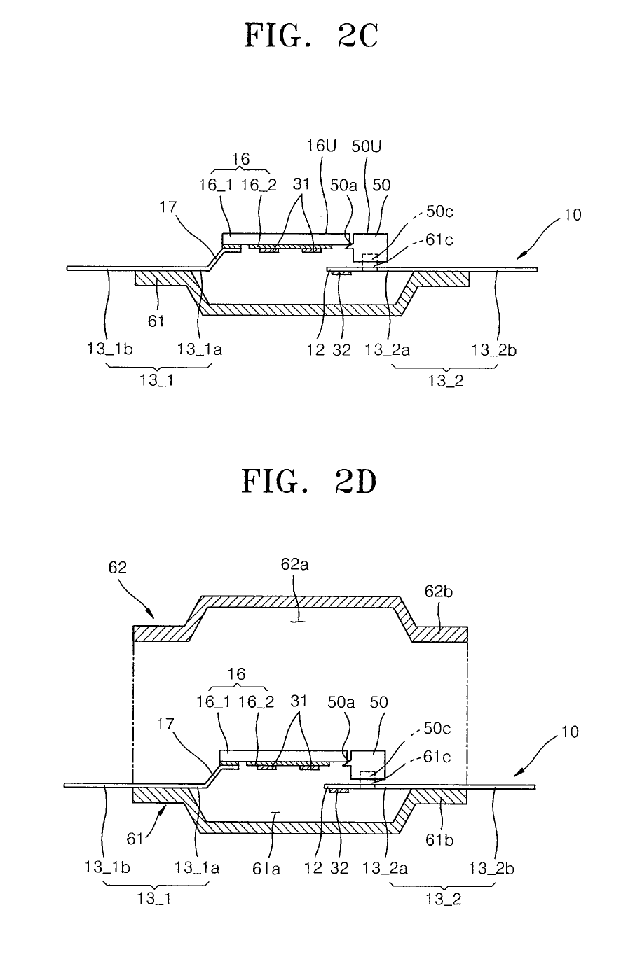

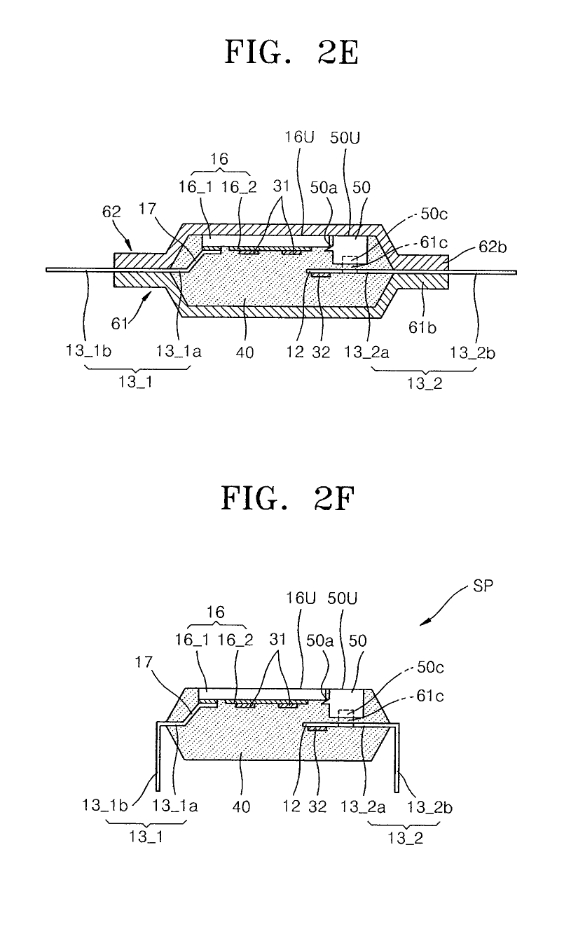

FIGS. 1A through 1E are perspective views of a method of fabricating a semiconductor package according to an embodiment of the present invention, and FIGS. 2A through 2F are cross-sectional views of the method of fabricating the semiconductor package according to the embodiment. In particular, FIGS. 2A through 2D and 2F are cross-sectional views taken along lines I-I of FIGS. 1A through 1E, respectively.

Referring to FIGS. 1A and 2A, a first mold die 61 is provided such that the first mold die 61 includes a first recess 61 a disposed in the center of the first mold die 61 and a first clamping portion 61b that encloses the first recess 61a. Two protrusions 61c are disposed opposite to each other on the first clamping portion 61b.

A lead frame 10 is provided on the first mold die 61, and the lead frame 10 includes a first die-pad 16 disposed in the center of the lead frame 10 and a plurality of leads disposed on opposing lateral sides of the first die-pad 16. Leads may be disposed on only one side or on both sides of the first die-pad 16.

Leads may include both power leads 13_1 for inputting and outputting power, and data leads 13_2 for inputting and outputting data. When the leads are disposed on both sides of first die-pad 16, power leads 13_1 may be disposed on a first side of the first die-pad 16, while data leads 13_2 may be disposed on a second side of the first die-pad 16. The power leads 13_1 can include connection bars 17 that protrude from the power leads 13_1 to connect with the first die-pad 16. Each of the power leads 13_1 may include an internal power lead 13_1a connected to an external power lead 13_1b, and each of the data leads 13_2 may include an internal data lead 13_2a connected to an external data lead 13_2b. The width of the external power lead 13_1b may be greater than that of the external data lead 13_2b, or vice-versa. The external power leads 13_1b may be connected to one another by a first dam bar 14, and the external data leads 13_2b may be connected to one another by a second dam bar 15.

The first die-pad 16 may be disposed above the power and data leads 13_1 and 13_2 as shown in FIG. 2A. The connection bar 17 can be angled to connect the power leads 13_1 with the first die-pad 16. A second die-pad 12 may be disposed adjacent to the first die-pad 16. In certain embodiments, the second die-pad 12 may be disposed between the first die-pad 16 and the data leads 13_2. The first die-pad 16 may include an interconnection layer 16_2 connected to a heat sink layer 16_1. The heat sink layer 16_1 may be a metal layer, a metal nitride layer, a ceramic layer, a resin layer, or a stack layer thereof. Exemplary metal layers can comprise a highly thermal conductive metal layer, for example, an aluminum layer, an aluminum alloy layer, a copper layer, or a copper alloy layer. Exemplary ceramic layers can include an Al₂O₃ layer or a BeO layer. Exemplary metal nitride layers may include an AIN layer or a SiN layer. An exemplary resin layer may be an epoxy resin layer. The interconnection layer 16_2 may be a copper layer or a copper alloy layer. In order to prevent oxidation of the interconnection layer 16_2, a nickel layer (not shown) and/or a gold layer (not shown) may be provided on the interconnection layer 16_2. The first die-pad 16 may be a direct bonded copper (DBC) substrate, an insulated metal substrate (IMS), a printed circuit board (PCB), or a flexible printed circuit board (FPCB). The connection bar 17 may be connected with the first die-pad 16 by using a conductive adhesive (not shown) between the connection bar 17 and the interconnection layer 16_2.

At least one first semiconductor chip 31 may be mounted on a bottom surface 16L of the interconnection layer 16_2 of the first die-pad 16. In certain embodiments, the first semiconductor chip 31 may be a power circuit chip for transforming or controlling power. The first semiconductor chip 31 can be a diode, a bipolar transistor, an insulated gate bipolar transistor (IGBT), a power metal oxide semiconductor field effect transistor (power MOSFET), or other suitable device.

A second semiconductor chip 32 may be mounted on a bottom surface of the second die-pad 12. In other implementations, a second semiconductor chip may be mounted (along with the first semiconductor chip 31) on the bottom surface 16L of the interconnection layer 16_2 of the first die-pad 16. The second semiconductor chip 32 may be a control circuit chip for controlling and driving the power circuit chip of the first semiconductor chip 31. Embodiments of the invention provide for a semiconductor package that is a “smart power module” or an “intelligent power module”, which comprises both a power circuit chip and a control circuit chip mounted on the lead frame 10 as described above.

The first semiconductor chip 31 may be electrically coupled with the lead frame 10 by any suitable means. For example, a bonding pad (not shown) of the first semiconductor chip 31 may be electrically connected to the internal power lead 13_1a by a first wire (not shown), which may be a metal wire such as an aluminum wire. Likewise, a bonding pad (not shown) of the second semiconductor chip 32 may be electrically connected to the internal data lead 13_2a by a second wire (not shown), which may be a metal wire such as a gold wire.

Referring to FIGS. 1B and 2B, the lead frame 10, on which the first and second semiconductor chips 31, 32 are mounted, is disposed on the first mold die 61. Specifically, the bottom surface of the first die-pad 16 (on which the first semiconductor chip 31 is mounted) is disposed opposite to the first recess 61a of the first mold die 61. In the present embodiment, the external power and data leads 13_1b and 13_2b and the dam bars 14 and 15 may be disposed on the first clamping portion 61b of the first mold die 61. The protrusions 61c of the mold die 61 may protrude above the data leads 13_2.

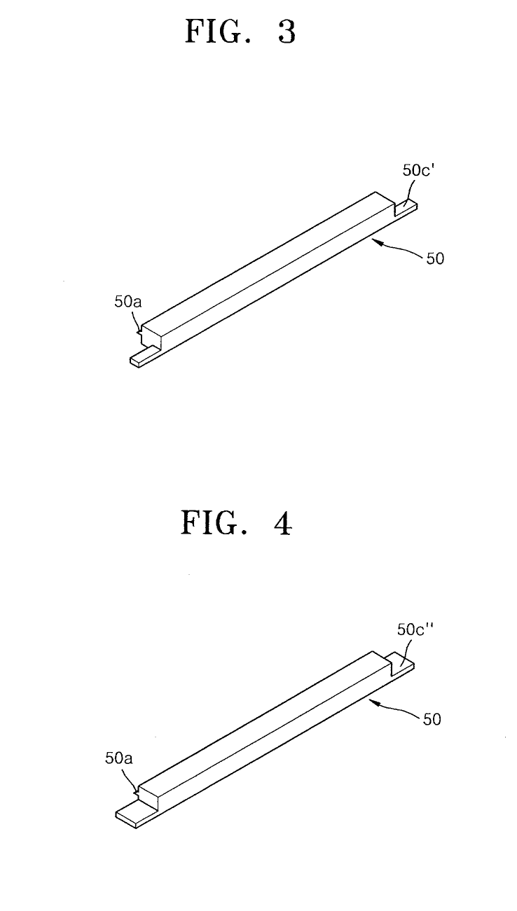

Referring to FIGS. 1C and 2C, a support plate 50 is placed (such as by a lateral movement as shown in FIG. 1C) between the first die-pad 16 and the lead frame 10. The support plate can overlap one or more leads in the plurality of leads. In certain embodiments, the support plate 50 can overlap the internal data leads 13_2a. The support place 50 can include wings 50c on the sides, that protrude from central lower portions of both lateral surfaces of the support plate 50, and correspond to the protrusions 61c of the mold 60. The protrusions 61c can support the support plate 50 by holding up the corresponding wings 50c. In the present embodiment, the wings 50c protrude from lower central portions of both the lateral surfaces of the support plate 50, however the present invention is not limited thereto. For example, the wings 50c may be replaced by wings 50c′ of FIG. 3 or wings 50c′ of FIG. 4. The wings may be formed as an integral part of support plate 50, or may be formed separately and attached to support plate 50 by suitable means as is known in the art.

The support plate 50 may include a support prop 50a that protrudes from a lateral surface of the support plate 50 which is to be adjacent to the first die-pad 16. In exemplary embodiments, the support prop can have a triangular cross section. The support prop 50a can have other suitable cross sections, such as a rectangle or other shape, in certain embodiments. The support prop 50a can extend in a lengthwise direction along a lateral surface of the support plate 50, to support the first die-pad 16. The support prop 50a can be in contact with the bottom surface 16L or a lower corner of the first die-pad 16. In certain embodiments, the support prop 50a supports the first die-pad 16 to maintain the first die-pad 16 at a horizontal position, so that the first die-pad 16 is level and does not slant downwards. The support prop 50a may be formed as an integral part of support plate 50, or may be formed separately and attached to support plate 50 by suitable means as is known in the art.

The support plate 50 may comprise an accessory heat sink such as a ceramic plate, a metal plate, a metal nitride plate, or a stack plate thereof. In certain examples, the metal plate may be an aluminum plate, an aluminum alloy plate, a copper plate, or a copper alloy plate; the ceramic plate may be formed of Al₂O₃ or BeO; the metal nitride plate may be formed of AIN or SiN.

When the first die-pad 16 includes the heat sink layer 16_1, a top surface 16U of the first die-pad 16 may be at substantially the same level with a top surface 50U of the support plate 50. Thus a top surface of the heat sink layer 16_1 may be substantially coplanar with the top surface 50U of the support plate 50, which can allow a portion of a second mold die (not shown) to form a solid seal with both the first die-pad 16 and support plate 50. This can prevent excess flash from forming during a molding step, as will be described in greater detail below.

The support prop 50a may be electrically insulated from the first die-pad 16. For this, the support plate 50 including the support prop 50a may comprise an insulating material. For example, support plate 50 can be a ceramic plate, a metal nitride plate, or a stack plate. Alternatively, when the support plate 50 comprises a conducting material such as a metal, the support prop 50a may be shaped so that it and the support plate 50 are not in contact with the interconnection layer 16_2 of the first die-pad 16. In such an embodiment, the support prop 50a may be in contact with only the heat sink layer 16_1 of the first die-pad 16. The portion of the heat sink layer 16_1 that is in contact with the support plate 50 may be formed of an insulating material.

Referring to FIGS. 1D and 2D, a second mold die 62 is disposed over the first mold die 61. The second mold die 62 can include a second recess 62a and a second clamping portion 62b that encloses the second recess 62a. The first and second clamping portions 61b and 62b may clamp between them the external power leads 13_1b, the external data leads 13_2b, the first dam bars 14 and the second dam bars 15.

Embodiments of the second clamping portion 62b may include grooves 62c that can accommodate both the corresponding protrusions 61c, and the wings 50c of the support plate 50 which are disposed thereon.

Referring to FIG. 2E, when the mold is closed (i.e., the first mold die 61 is brought in contact with the second mold die 62), the first and second clamping portions 61b and 62b can clamp the external power and data leads 13_1b and 13_2b and the dam bars 14 and 15. In this embodiment, the protrusions 61c and the grooves 62c may correspondingly clamp between them the wings 50c of support plate 50. Thus, the support plate 50 can be held in a fixed position. In certain implementations, the support plate 50 can be held tightly against the bottom surface of the second recess 62a of the second mold die 62. In these embodiments, the first die-pad 16 can be held in place by the support prop 50a of the support plate 50. As a result, the first die-pad 16 can be closely adhered to the bottom surface of the second recess 62a, such that there is little to no space left between the die pad and second mold die, helping to reduce excess mold flash.

An encapsulant, such as epoxy mold compound (EMC), may be injected into a cavity formed by the first and second recesses 61a and 62a. Thereafter, the injected encapsulant is cured to result in a package body 40 encapsulating structures including the first and second semiconductor chips 31 and 32, the first and second die-pads 16 and 12, the internal power and data leads 13_1a and 13_2a, and the support plate 50. During the encapsulation process, as described above, the support plate 50 and the first die-pad 16 are closely adhered to the bottom surface of the second recess 62a. This can prevent the encapsulant from flowing onto the top surface 16U of the first die-pad 16. Thus, mold flash is not formed on the top surface 16U of the first die-pad 16.

Referring to FIGS. 1E and 2F, the first and second mold dies 61 and 62 are removed to expose the package body 40. The external power and data leads 13_1b and 13_2b may protrude from a pair of lateral surfaces of the package body 40. The wings 50c of the support plate 50 may protrude from another pair of lateral surfaces of the package body 40. In certain embodiments, the wings 50c do not protrude and are located entirely within the package body 40. The top surface 16U of the first die-pad 16 (specifically, the top surface of the heat sink layer 16_1) and the top surface 50U of the support plate 50 may be exposed outside of a top surface of the package body 40. In this case, since no mold flash is generated on the top surface of the heat sink layer 161, the heat sink layer 16_1 can effectively dissipate the heat generated by the first semiconductor chip 31. Furthermore, the heat generated by the first semiconductor chip 31 is also transmitted through the support prop 50a to the support plate 50 and then dissipated through the exposed top surface 50U of the support plate 50. Thus, the heat emission efficiency of the heat sink layer 16_1 can be further enhanced by use of the support plate 50.

Subsequently, a trimming process can be performed to remove the dam bars 14 and 15 from the lead frame 10 so that only the external power and data leads 13_1b and 13_2b can be left outside of the package body 40. After that, a bending process is performed to bend the external power and data leads 13_1b and 13_2b, thereby completing the fabrication of the semiconductor package.

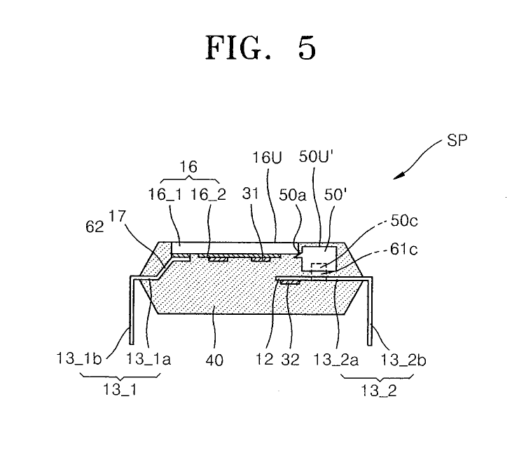

FIG. 5 is a cross-sectional view of a semiconductor package according to another embodiment of the present invention.

Referring to FIG. 5, a top surface 50U′ of a support plate 50′ may be disposed at a lower level than a top surface 16U of a die-pad 16. Hence, there can be space between a bottom surface of a mold die (not shown) and the top surface 50U. During encapsulation, an encapsulant may flow onto the top surface 50U′ of the support plate 50′. In this embodiment, package body 40 covers the top surface 50U′ of the support plate 50′ (i.e. the top surface 50U′ is not exposed by package body 40). The support prop 50a of the support plate 50′ can support the die-pad 16 such that it is held to closely adhere to the inside of a mold die (not shown). This can prevent mold flash from being formed on the top surface 16U of the die-pad 16, specifically, on a top surface of a heat sink layer 16_1.

According to the present invention as described above, a support plate includes a support prop to support and maintain a die-pad at a level position, so that the die-pad does not tilt or slant sideways. As a result, the die-pad can be held to closely adhere to the inside mold die during an encapsulation process, with little to no space between the die-pad and the inside of the mold die, such that mold flash does not form on the die-pad.

Furthermore, both a heat sink layer (attached to or formed as a part of the die-pad), and the support plate may be exposed outside of a package body. In embodiments of the invention, no mold flash is formed on the heat sink layer. This allows for the heat sink layer to effectively dissipate heat generated within the package. Furthermore, there is no need for a flash removal step, increasing production efficiency and reducing costs.

Also, the die-pad can be thermally connected to the support plate through contact with the support prop. In this way, heat can also be dissipated through the support plate. Thus, the heat emission efficiency of the heat sink layer can be further improved due to greater surface area exposure outside the package body.

As used herein the terms “top” and “bottom” surfaces, “above” and “below” are used in the context of relativity with respect to a circuit board upon which the semiconductor die packages according to embodiments of the invention are mounted. Such positional terms may or may not refer to absolute positions of such packages. It will also be understood that when a layer is referred to as being “on” another layer or substrate, it can be directly on the other layer or substrate or intervening layers may also be present.

The semiconductor die packages described above can be used in electrical assemblies including circuit boards with the packages mounted thereon. They may also be used in systems such as phones, computers, etc.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly shown and described with reference to embodiments thereof, it will be understood by one of ordinary skill in the art that various changes in form and details may be made therein without departing from the spirit and scope of the present invention as defined by the following claims.

What is claimed is:

1. A semiconductor package comprising:
a first die-pad having a bottom surface;
a first semiconductor chip mounted on the bottom surface of the first die-pad;
a support plate disposed adjacent to a lateral surface of the first die-pad;
a support prop protruding from a lateral surface of the support plate, wherein the support prop supports the first die-pad; and
a package body for encapsulating the first die-pad, the semiconductor chip, and the support plate.

2. The semiconductor package of claim 1, wherein the first die-pad includes a heat sink layer and an interconnection layer attached to the heat sink layer, wherein the first semiconductor chip is mounted on the interconnection layer, and further wherein the heat sink layer is exposed outside of the package body.

3. The semiconductor package of claim 2, wherein the heat sink layer is one selected from the group consisting of a metal layer, a metal nitride layer, a ceramic layer, a resin layer, and a stack layer thereof.

4. The semiconductor package of claim 1, wherein the first die-pad is one selected from the group consisting of a printed circuit board, a flexible printed circuit board, an insulated metal substrate, and a direct bonded copper substrate.

5. The semiconductor package of claim 1, wherein the support plate is an accessory heat sink, which is exposed outside of the package body.

6. The semiconductor package of claim 5, wherein the accessory heat sink is one selected from the group consisting of a ceramic plate, a metal plate, a metal nitride plate, and a stack plate thereof.

7. The semiconductor package of claim 1, wherein a plurality of internal leads are disposed on opposing lateral sides of the first die-pad, and further wherein the support plate overlaps with one or more leads in the plurality of internal leads.

8. The semiconductor package of claim 1, wherein the semiconductor chip is a power circuit chip.

9. The semiconductor package of claim 8, further comprising:
second die-pad disposed adjacent to the first die-pad; and
a second semiconductor chip mounted on the second die-pad, wherein the second semiconductor chip is configured to control the power circuit chip.

10. The semiconductor package of claim 8, further comprising:
internal power leads disposed on a first side of the first die pad, wherein the internal power leads are connected to the first die pad;
internal data leads disposed on a second side of the first die pad, wherein the internal data leads are not directly connected to the first die pad, and further wherein the support plate overlaps one or more of the internal data leads.

11. A semiconductor package comprising:
a die-pad, wherein the die pad includes a heat sink layer and an interconnection layer disposed on a bottom surface of the heat sink layer;
a power circuit chip mounted on the interconnection layer;
an accessory heat sink disposed adjacent to a lateral surface of the die-pad;
a support prop protruding from a lateral surface of the accessory heat sink, wherein the support prop supports the die-pad; and
a package body for encapsulating the die-pad, the power circuit chip, and the accessory heat sink, wherein the heat sink layer and the accessory heat sink are exposed outside of the package body.

12. A method of fabricating a semiconductor package, the method comprising:
providing a lead frame including a first die-pad, wherein a first semiconductor chip is mounted on a bottom surface of the first die-pad;
disposing the lead frame on a first mold die, wherein the first mold die includes a recess and a clamping portion enclosing the recess;
disposing a support plate adjacent to a lateral surface of the first die-pad, wherein a support prop protrudes from the support plate, and is configured to support the first die-pad;
disposing a second mold die on the first mold die, wherein the first and second mold dies form a cavity containing the lead frame, first semiconductor chip, and support plate; and
injecting an encapsulant into the cavity to form a package body that encapsulates the first die-pad, the first semiconductor chip, and the support plate.

13. The method of claim 12, wherein the first mold die includes protrusions, wherein the protrusions support the support plate,
and wherein the second mold die includes grooves corresponding to the protrusions.

14. The method of claim 13, wherein the support plate includes wings that protrude from the support plate, wherein the wings are supported by the protrusions.

15. The method of claim 12, wherein the first die-pad includes a heat sink layer and an interconnection layer disposed on the heat sink layer, wherein the first semiconductor chip is mounted on the interconnection later, and further wherein the heat sink layer is exposed outside of the package body.

16. The method of claim 12, wherein the support plate is an accessory heat sink and is exposed outside of the package body.

17. The method of claim 12, wherein the first semiconductor chip is a power circuit chip.

18. The method of claim 17, further comprising:
a second die-pad disposed adjacent to the first die-pad; and
a second semiconductor chip mounted on the second die-pad, wherein the second semiconductor chip is configured to control the power circuit chip.
